(19) United States
(12) Patent Application Publication
(10) Pub. No.: US 2010/0219422 A1
(43) Pub. Date: Sep. 2, 2010

(54) PHOTO-COUPLER

(75) Inventors: Chao-Hsuan SU, Tucheng City (TW); Lu-Ming LAI, Tucheng City (TW); Ying-Zhong CHEN, Tucheng City (TW)

Correspondence Address: PATTERSON THUENTE CHRISTENSEN PEDERSEN, P.A., 4800 IDS CENTER, 80 SOUTH 8TH STREET, MINNEAPOLIS, MN, 55402-2100, US

(73) Assignee: EVERLIGHT ELECTRONICS CO., LTD., Tucheng City (TW)

(21) Appl. No.: 12/711,921

(22) Filed: Feb. 24, 2010

(30) Foreign Application Priority Data
Feb. 27, 2009 (TW) 098106353

(51) Int. Cl. H01L 33/00

(52) U.S. Cl. 257/82; 257/84; 257/E33.058; 257/E33.076; 257/E33.067

(57) ABSTRACT

A photo-coupler is provided. The photo-coupler comprises a light emitting chip, a light-sensing chip, a light-transmissive inner encapsulant package and an outer package. Both the light emitting chip and the light-sensing chip face the same direction, while the light-sensing chip receives a light beam emitted by the light emitting chip. The light-transmissive inner encapsulant package encloses the light emitting chip and the light-sensing chip, while the outer package encloses the light-transmissive inner encapsulant package. An interface is formed between the light-transmissive inner encapsulant package and the outer package for reflecting the light beam. A reflective curve surface adjacent to the light emitting chip is formed on the interface of the light-transmissive inner encapsulant package for reflecting and converging the first portion of the light beam to the light-sensing chip.

### CROSS-REFERENCES TO RELATED APPLICATIONS

This application claims priority to Taiwan Patent Application No. 098106353 filed on Feb. 27, 2009, the disclosure of which is incorporated by reference herein in their entirety.

### BACKGROUND OF THE INVENTION

1. Field of the Invention

The present invention relates to a photo-coupler, and particularly, to a photo-coupler having a high operating voltage.

2. Descriptions of the Related Art

Photo-couplers are circuit safety devices which, when combined with a light emitting chip and a photo sensing chip, convert an electric signal into a light signal and then convert the light signal back into an electric signal. Photo-couplers can obviate bursts and other instable conditions from the source end and prevent consequent burning-out or failure of circuits at the receiving end when the electrical connection is made simply via a circuit.

As shown in FIG. 1, a conventional photo-coupler 1 comprises a light emitting chip 12 and a light-sensing chip 13 opposite each other in the vertical direction. The light emitting chip 12 and the light-sensing chip 13 are enclosed by an inner package 15, which is made of an insulator to electrically insulate the light emitting chip 12 and the light-sensing chip 13 from each other. The inner package 15 is in turn enclosed by an opaque outer package 16, which generally has a black color adapted to block and absorb light from both the inside and the outside. When an input electric signal is transmitted to the light emitting chip 12, the light emitting chip 12 converts the input electric signal into a light beam 14a, and the light beam 14a is then received by the light-sensing chip 13 where it is converted into an output electric signal. Thus, the conventional photo-coupler 1 accomplishes a cycle of electric signal/light signal conversion and light signal/electric signal conversion to play the role of a circuit safety device.

To block light from both inside and outside of the outer package 16, a large amount of filler must be filled in the plastic matrix to give it a black color. However, use of the filler changes the thermal expansion coefficient of the outer package 16 to a great extent. Therefore, an appropriate amount of filler must also be filled in the inner package 15 to make the thermal expansion coefficient of the inner package 15 approximately that of the outer package 16, so that an undue temperature rise and consequent deformation or damage of the inner package 15 and the outer package 16 due to a large difference in the thermal expansion coefficients therebetween can be avoided. Because of this, the inner package 15 is generally white colored and forced to have a low light transmittance. However, the low light transmittance of the inner package 15 further prevents the distance between the light emitting chip 12 and the light-sensing chip 13 from increasing, otherwise the light beam 14a from the light emitting chip 12 would experience an excessive loss when transmitting through the inner package 15 and the light-sensing chip 13 would fail to receive sufficient light that is necessary for converting the light signal into an electric signal.

Furthermore, the conventional photo-coupler 1 has an insulation voltage (V_{ISO}) substantially less than or equal to 5000 V, so the light emitting chip 12 and the light-sensing chip 13 must have a minimum distance at least ranging substantially from 0.4 mm to 0.6 mm to avoid point discharge. However, in case the operating voltage needs to be substantially higher than 8000 V, the minimum distance between the light emitting chip 12 and the light-sensing chip 13 must be substantially greater than 3.0 mm and the creepage distance must be substantially greater than 8.0 mm according to the safety regulations. Under such operating conditions, due to the extremely low light transmittance of the inner package 15, the light beam 14a emitted from the light emitting chip 12 would experience such an excessive loss that the light-sensing chip 13 might fail to convert the light signal into the electric signal normally, causing failure of the photo-coupler 1 to operate under such conditions.

It is important in the art to provide a photo-coupler capable of operating at a high voltage.

### SUMMARY OF THE INVENTION

One objective of the present invention is to provide a photo-coupler capable of operating at a high voltage and obviating an excessive light loss that would cause operational failure of the photo-coupler.

The photo-coupler of the present invention comprises a light emitting chip, a light-sensing chip, a light-transmissive inner encapsulant package and an outer package. Both the light emitting chip and the light-sensing chip face towards a same direction, and are adapted to emit and receive a light beam respectively. The light-transmissive inner encapsulant package encloses the light emitting chip and the light-sensing chip, while the outer package encloses the light-transmissive inner encapsulant package and forms an interface with the light-transmissive inner encapsulant package for reflecting the light beam. The light-transmissive inner encapsulant package is formed with a reflective curved surface adjacent to the light emitting chip which, as enclosed by the outer package, is adapted to reflect and converge a first portion of the light beam to the light-sensing chip.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

FIG. 1 is a schematic cross-sectional side view of the conventional photo-coupler;

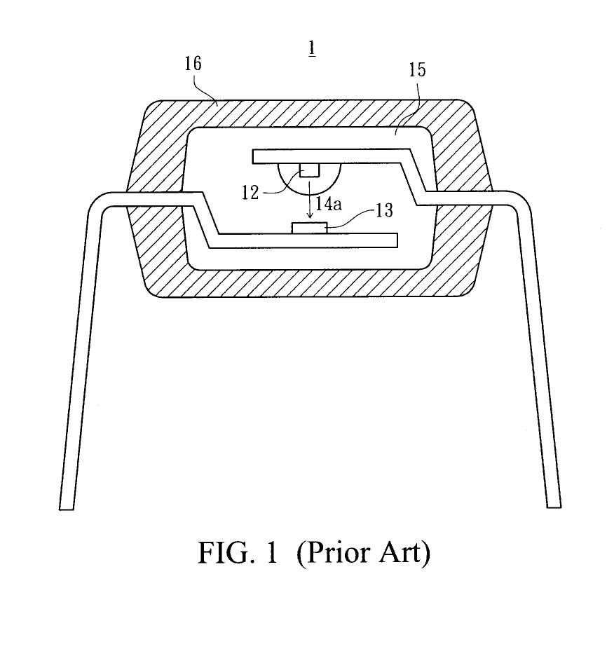

FIG. 2 is a schematic cross-sectional bottom view of a photo-coupler of the present invention;

FIG. 3 is a schematic cross-sectional side view of the photo-coupler of the present invention; and

FIG. 4 is a schematic perspective view of a light-transmissive inner encapsulant package of the present invention.

### DESCRIPTION OF THE PREFERRED EMBODIMENT

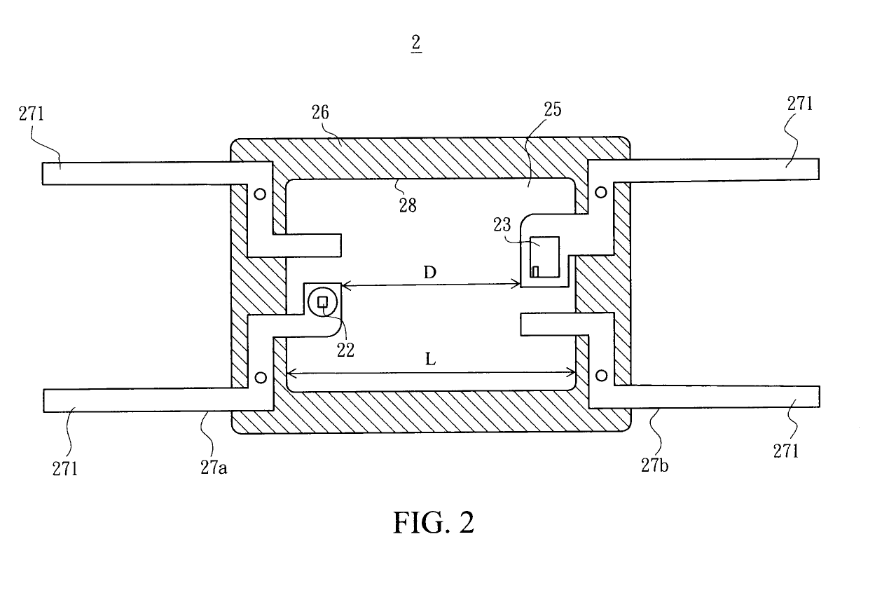

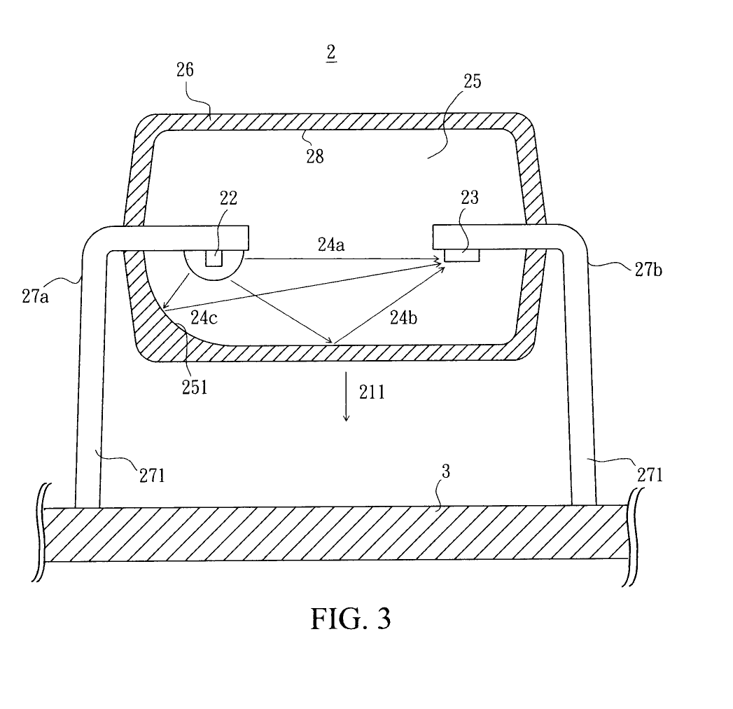

In references to both FIGS. 2 and 3, a photo-coupler 2 disclosed in the present invention comprises a light emitting chip 22, a light-sensing chip 23, a light-transmissive inner encapsulant package 25 and an outer package 26. The light emitting chip 22 and the light-sensing chip 23 both are disposed in a same plane and face towards a same direction 211 of the photo-coupler 2.

The light emitting chip 22, after receiving an input electric signal, is adapted to generate and emit a first portion 24c, a second portion 24b and a third portion 24a of a light beam. After receiving the first portion 24c, the second portion 24b and the third portion 24a of the light beam, the light-sensing chip 23 converts them into an output electric signal and transmits the signals. The light-transmissive inner encapsulant package 25 encloses the light emitting chip 22 and the light-sensing chip 23, while the outer package 26 encloses the light-transmissive inner encapsulant package 25. With an interface 28 formed between the light-transmissive inner encapsulant package 25 and the white outer package 26, the outer package 26 reflects the first portion 24c, the second portion 24b and the third portion 24a of the light beam to the light-sensing chip 23 through the light-transmissive inner encapsulant package 25.

In the present invention, the light emitting chip 22 should be an infrared light emitting diode (IR LED), while the light-sensing chip 23 is a photo transistor. The material of the light-transmissive inner encapsulant package 25 preferably comprises epoxy resin, and to enhance the reflectivity, the material of the outer package 26 should preferably comprise an epoxy resin matrix and white TiO₂ filler. Hence, with the above arrangement, the light-transmissive inner encapsulant package 25 encloses the light emitting chip 22 and the light-sensing chip 23, while the outer package 26 in turn encloses the light-transmissive inner encapsulant package 25. The white outer package 26 can effectively reflect the first portion 24c, the second portion 24b and the third portion 24a of the light beam from the light emitting chip 22 to the light-sensing chip 23. As compared to the light beam 14a in the conventional photo-coupler 1 which is transmitted through the white inner package 15, the first portion 24c, the second portion 24b and the third portion 24a of the light beam in the present invention are transmitted through the light-transmissive inner encapsulant package 25 with little loss between the light emitting chip 22 and the light-sensing chip 23. As a result, the distance D between the light emitting chip 22 and the light-sensing chip 23 is permitted to be enlarged to reinforce the insulation capability of the light-transmissive inner encapsulant package 25, thereby allowing the photo-coupler 2 of the present invention to withstand a higher operating voltage.

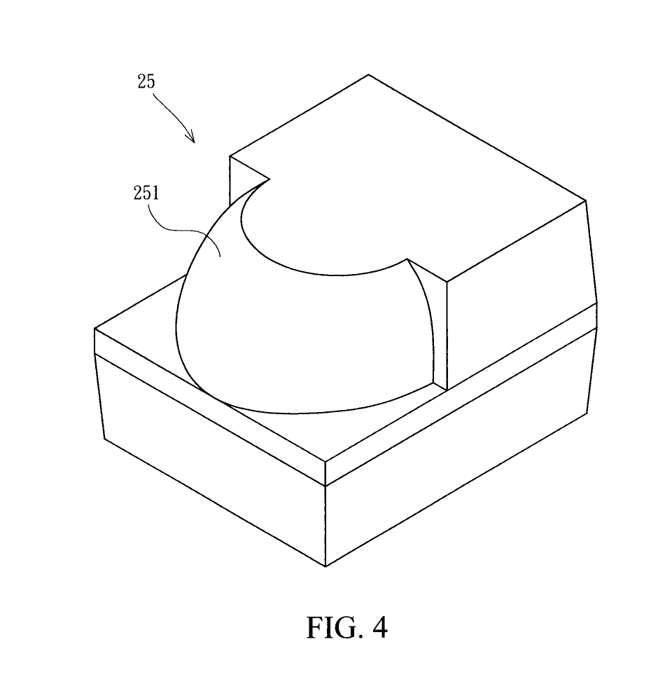

As shown in FIGS. 3 and 4, to further increase the efficiency of transmitting the first portion 24c, the second portion 24b and the third portion 24a of the light beam from the light emitting chip 22 through the light-transmissive inner encapsulant package 25 to the light-sensing chip 23, the light-transmissive inner encapsulant package 25 is formed with a reflective curved surface 251 adjacent to the light emitting chip 22 for reflecting and converging the first portion 24c of the light beam to the light-sensing chip 23. In the most preferred embodiment of the present invention, the reflective curved surface 251 is disposed adjacent to the light emitting chip 22 and at a side opposite the light-sensing chip 23 with respect to the light emitting chip 22; i.e., the light emitting chip 22 is disposed between the light-sensing chip 23 and the reflective curved surface 251. When enclosed by the outer package 26, the reflective curved surface 251 is adapted to reflect and converge the first portion 24c of the light beam to the light-sensing chip 23.

In addition to the first portion 24c of the light beam being reflected and converged by the reflective curved surface 251 to the light-sensing chip 23, as shown in FIG. 3, the third portion 24a of the light beam transmits linearly through the light-transmissive inner encapsulant package 25 from the light emitting chip 22 to the light-sensing chip 23 directly as shown, and the second portion 24b of the light beam is reflected by the outer package 26 through the light-transmissive inner encapsulant package 25 to the light-sensing chip 23. Thereby, the photo-coupler 2 of the present invention can utilize the light beam emitted from the light emitting chip 22 in a more efficient way, which allows to further increase the minimum distance D between the light emitting chip 22 and the light-sensing chip 23 and enable the photo-coupler 2 of the present invention to withstand a higher operating voltage.

In the most preferred embodiment of the present invention, the photo-coupler 2 is mounted with the direction 211 facing towards a circuit board 3 (i.e., both the light emitting chip 22 and the light-sensing chip 23 face towards the underside of the photo-coupler 2) to completely eliminate the effect of environmental light transmitted through the white outer package 26 on the light-sensing chip 23. Additionally, at least two lead frames 27a, 27b of the photo-coupler 2 of the present invention extend outward away from each other, with a plurality of pins 271 thereof extending also downwards to electrically connect with the circuit board 3. The light emitting chip 22 and the light-sensing chip 23 are disposed on the first lead frame 27a and the second lead frame 27b respectively to allow the light emitting chip 22 to receive the input electric signal and the light-sensing chip 23 to transmit the output electric signal. As will be readily appreciated by those of ordinary skill in the art, the first lead frame 27a and the second lead frame 27b may also extend towards a same direction instead.

In reference to FIG. 2, to enable the photo-coupler 2 of the present invention to operate at a high operating voltage that is substantially higher than 8000 V, the light emitting chip 22 and the light-sensing chip 23 are disposed adjacent to the two ends of a long edge L of the light-transmissive inner encapsulant package 25 respectively. As a consequence, the minimum distance D between the light emitting chip 22 and the light-sensing chip 23 may be substantially greater than or equal to 3.0 mm, and the creepage distance thereof is substantially greater than 8.0 mm. Correspondingly, the reflective curved surface 251 is disposed at the end of the long edge L of the light-transmissive inner encapsulant package 25 adjacent to the light emitting chip 22. Accordingly, by increasing the distance between the light emitting chip 22 and the light-sensing chip 23, the photo-coupler 2 of the present invention is adapted to operate at a high operating voltage and prevent point discharge. Moreover, due to the disposition of the light-transmissive inner encapsulant package 25, the outer package 26 and the reflective curved surface 251, the transmission efficiency of the first portion 24c, the second portion 24b and the third portion 24a of the light beam will not decrease as the distance between the light emitting chip 22 and the light-sensing chip 23 increases.

The above disclosure is related to the detailed technical contents and inventive features thereof. People skilled in this field may proceed with a variety of modifications and replacements based on the disclosures and suggestions of the invention as described without departing from the characteristics thereof Nevertheless, although such modifications and replacements are not fully disclosed in the above descriptions, they have substantially been covered in the following claims as appended.

What is claimed is:

1. A photo-coupler, comprising:
a light emitting chip facing a direction disposed, for emitting a light beam;
a light-sensing chip facing the direction disposed, for receiving the light beam;
a light-transmissive inner encapsulant package enclosing the light emitting chip and the light-sensing chip; and
an outer encapsulant package enclosing the light-transmissive inner encapsulant package and forming an interface with the light-transmissive inner encapsulant package for reflecting the light beam;
wherein the interface has a reflective curved surface adjacent to the light emitting chip for reflecting and converging a first portion of the light beam from the light emitting chip to the light-sensing chip.

2. The photo-coupler as claimed in claim 1, wherein the reflective curved surface is disposed on a side opposite to the light-sensing chip with regard to the light emitting chip.

3. The photo-coupler as claimed in claim 1, wherein the light emitting chip and the light-sensing chip are disposed on the same plane.

4. The photo-coupler as claimed in claim 1, wherein the interface comprises a reflective surface between the light emitting chip and the light-sensing chip for reflecting a second portion of the light beam emitting from the light emitting chip to the light-sensing chip.

5. The photo-coupler as claimed in claim 4, wherein a third portion of the light beam emitting from the light emitting chip transmits through the light-transmissive inner encapsulant package to the light-sensing chip directly.

6. The photo-coupler as claimed in claim 1, wherein the photo-coupler further comprises at least two lead frames, and the light emitting chip and the light-sensing chip are disposed on the lead frames respectively.

7. The photo-coupler as claimed in claim 6, wherein the at least two lead frames extend outward away from each other.

8. The photo-coupler as claimed in claim 3, wherein the photo-coupler further comprises at least two lead frames, the light emitting chip and the light-sensing chip are disposed on the lead frames respectively.

9. The photo-coupler as claimed in claim 8, wherein the at least two lead frames extend outward away from each other.

10. The photo-coupler as claimed in claim 1, wherein the material of the light-transmissive inner encapsulant package comprises epoxy resin.

11. The photo-coupler as claimed in claim 1, wherein the material of the outer package comprises epoxy resin matrix and white filler.

12. The photo-coupler as claimed in claim 11, wherein the white filler comprises TiO₂.

13. The photo-coupler as claimed in claim 6, wherein the at least two lead frames extend in a same direction.

14. The photo-coupler as claimed in claim 8, wherein the at least two lead frames extend in a same direction.

15. A photo-coupler, comprising:
a light emitting chip disposed on a first lead frame for emitting a light beam;
a light-sensing chip disposed on a second lead frame for receiving the light beam, in which the light emitting chip and the light-sensing chip face a same direction and are disposed on a same plane;
a light-transmissive inner encapsulant package enclosing the light emitting chip and the light-sensing chip; and
an outer package enclosing the light-transmissive inner encapsulant package and forming an interface with the light-transmissive inner encapsulant package for reflecting the light beam;
wherein the interface has a reflective curved surface adjacent to the light emitting chip for reflecting and converging a first portion of the light beam emitting from the light emitting chip to the light-sensing chip.

16. The photo-coupler as claimed in claim 15, wherein the reflective curved surface is disposed on a side opposite to the light-sensing chip with regard to the light emitting chip.

17. The photo-coupler as claimed in claim 15, wherein the interface comprises a reflective surface between the light emitting chip and the light-sensing chip for reflecting a second portion of the light beam emitting from the light emitting chip to the light-sensing chip.

18. The photo-coupler as claimed in claim 15, wherein the first lead frame and the second lead frame extend outward away from each other or extend in a same direction.

19. A photo-coupler, comprising:
a light emitting chip emitting a light beam;
a light-sensing chip receiving the light beam; and
a light-transmissive inner encapsulant package enclosing the light emitting chip and the light-sensing chip;
wherein the surface of the light-transmissive inner encapsulant package adjacent to the light emitting chip is formed with a reflective curved surface for reflecting and converging a first portion of the light beam emitting from the light emitting chip to the light-sensing chip.

20. The photo-coupler as claimed in claim 19, wherein the reflective curved surface is disposed on a side opposite to the light-sensing chip with regard to the light emitting chip.
